(19) United States
(12) Patent Application Publication
(10) Pub. No.: US 2018/0212029 A1
(43) Pub. Date: Jul. 26, 2018

(54) SEMICONDUCTOR DEVICES EMPLOYING REDUCED AREA CONFORMAL CONTACTS TO REDUCE PARASITIC CAPACITANCE, AND RELATED METHODS

(71) Applicant: QUALCOMM Incorporated, San Diego, CA (US)

(72) Inventors: Jeffrey Junhao Xu, San Diego, CA (US); Mustafa Badaroglu, Kessel-Lo (BE); John Jianhong Zhu, San Diego, CA (US)

(21) Appl. No.: 15/874,005

(22) Filed: Jan. 18, 2018

Related U.S. Application Data
(60) Provisional application No. 62/448,580, filed on Jan. 20, 2017.

(51) Int. Cl. H01L 29/417; H01L 27/088; H01L 29/66; H01L 29/10; H01L 29/06; H01L 29/16; H01L 29/08; H01L 29/78

(52) U.S. Cl. CPC H01L 29/41791; H01L 27/0886; H01L 29/41766; H01L 29/66795; H01L 29/66545; H01L 29/0673; H01L 29/16; H01L 29/0847; H01L 29/785; H01L 29/1033

(57) ABSTRACT

Semiconductor devices employing reduced area conformal contacts for reducing parasitic capacitance and improving performance, and related methods are disclosed. The area of the source/drain contacts for providing an electrical contract to a source/drain is reduced in size to reduce parasitic capacitance between a gate and the source/drain contacts for improved performance. To mitigate or avoid increase in contact resistance between the source/drain contacts and source/drain, a conformal contact layer of a desired thickness is disposed adjacent to the source/drain to reduce the source/drain contact resistance. Thus, the source/drain contacts may only have to extend down adjacent to an upper region of the source/drain to still achieve a desired, lower contact resistance with the source/drain contacts, which results in a reduced area source/drain contact for reducing parasitic capacitance.

### PRIORITY CLAIM

The present application claims priority under 35 U.S.C. § 119(e) to U.S. Patent Application Ser. No. 62/448,580 filed on Jan. 20, 2017 and entitled “SEMICONDUCTOR DEVICES EMPLOYING REDUCED AREA WRAP AROUND CONTACTS (WACS) TO REDUCE PARASITIC CAPACITANCE, AND RELATED METHODS,” the contents of which is incorporated herein by reference in its entirety.

### BACKGROUND

### I. Field of the Disclosure

The technology of the disclosure relates generally to semiconductor devices, and more specifically, to forming conformal gate structures in semiconductor devices, such as fin field-effect transistors (FETs) (FinFETs) and gate all around (GAA) nanowire transistors.

### II. Background

Transistors are essential components in modern electronic devices, and large numbers of transistors are employed in integrated circuits (ICs) therein. For example, components such as central processing units (CPUs) and memory systems each employ a large quantity of transistors for logic circuits and memory devices.

As electronic devices become more complex in functionality, so does the need to include a greater number of transistors in such devices. But as electronic devices are provided in increasingly smaller packages, such as in mobile devices for example, there is a need to provide a greater number of transistors in a smaller IC chip. This increase in the number of transistors is achieved in part through continued efforts to miniaturize transistors in ICs (i.e., placing increasingly more transistors into the same amount of space). As a result, gate lengths are also scalably reduced, thereby reducing channel length of the transistors and interconnects. In particular, as channel length in planar transistors is reduced such that the channel length is of the same order of magnitude as depletion layer widths, short channel effects (SCEs) can occur that degrade performance. More specifically, SCEs in planar transistors cause increased current leakage, reduced threshold voltage, and/or threshold voltage roll-off (i.e., reduced threshold voltage at shorter gate lengths), and therefore, reduced gate control.

To overcome the SCEs due to the reduction in gate and channel lengths in planar transistor, gate all around (GAA) transistors have been developed. A GAA transistor includes a gate material wrapped around at least a portion of a channel structure to provide better gate control over an active channel therein. Better gate control provides reduced current leakage and increased threshold voltage compared to a planar transistor of a similar footprint. An example of a GAA transistor is a complementary metal-oxide semiconductor (CMOS) fin field-effect transistor (FET) (FinFET). A FinFET provides a channel structure formed by thin silicon (Si) “fins,” and a gate that wraps around portions of the fins. FIG. 1 illustrates a conventional CMOS FinFET 100 (“FinFET 100”) as an example. The FinFET 100 includes a substrate 102 and fins 104A, 104B made of a semiconductor material and disposed above the substrate 102 to form a semiconductor material structure 106 across the FinFET 100. The FinFET 100 further includes source/drain elements 108A, 108B disposed above the fins 104A, 104B, respectively, to provide a source and drain for the FinFET 100. The FinFET 100 further includes a source/drain contact 112A disposed on the substrate 102 to provide a contact to the source/drain elements 108A, 108B. The FinFET 100 further includes a source/drain contact 112B on a side 110 of the FinFET 100 to provide a contact to drain/source regions (not shown). The FinFET 100 further includes spacer layers 114A and 114B (e.g., a Nitride-based low-k material or air) disposed on the substrate 102 to isolate the source/drain contacts 112A, 112B, respectively, from a “wrap-around” gate 116 disposed on the substrate 102 and over the fins 104A, 104B between the spacer layers 114A, 114B. The FinFET 100 further includes a gate contact 118 disposed on the gate 116 to provide a contact to the gate 116. The FinFET 100 further includes an interlayer dielectric (ILD) 120 to isolate active components of the FinFET 100 from other devices disposed near the FinFET 100.

One substantial factor that contributes to external resistance of the FinFET 100 in FIG. 1, and thus its performance, is the contact resistance between the source/drain elements 108A, 108B, the fins 104A, 104B, and the source/drain contacts 112A, 112B. High contact resistance can result in degradation of performance, errors in data, and increases in heat and power loss, to name a few effects. Conventionally, the source/drain elements 108A, 108B in the FinFET 100 are epitaxially grown to provide as large as possible of a contact area between the source/drain elements 108A, 108B, and the fins 104A, 104B to provide a lower contact resistance. However, contact resistance may still be performance and scaling limiters in the FinFET 100 in FIG. 1 due to highly scaled fin pitch P_{f} of the fins 104A, 104B as well as a gate pitch of the gate 116. As the fin pitch P_{f} of the fins 104A, 104B and the gate pitch of the gate 116 are scaled down, there is less contact area between the source/drain elements 108A, 108B, and the fins 104A, 104B to provide a lower contact resistance. This is also the gate in gate-all-around (GAA) transistors.

### SUMMARY OF THE DISCLOSURE

Aspects disclosed herein include semiconductor devices employing reduced area conformal contacts for reduced parasitic capacitance. Related methods are also disclosed. Reducing side wall surface area of conformal contacts can reduce parasitic capacitance between contacts and a gate of the semiconductor device to improve device performance. In this regard, in exemplary aspects disclosed herein, a semiconductor device is provided that includes a conduction channel formed of one or more channel structures formed of a semiconductor material. For example, if the semiconductor device is a fin field-effect transistor (FET) (FinFET), the channel structure(s) is a fin of a semiconductor material. The semiconductor device also include a source and a drain that are formed (e.g., by doping the channel structure or epitaxial growth on the channel structure) in contact with the channel structure to form a conduction path between the source and the drain when the conduction channel is activated. A “wrap-around” gate of a gate material is disposed over at least a portion of the conduction channel to provide electrostatic control of the conduction channel. The semiconductor device also includes source and drain contacts formed of a conductive contact fill material (e.g., a fill metal material) in contact with a contact layer (e.g., a contact metal or silicide) disposed in contact to the respective source and drain, to provide electrical contacts to the source and drain. A spacer of a dielectric material is located between the gate and the source and drain contacts.

To reduce the parasitic capacitance between the gate and the source and/or drain (source/drain) contacts for improved performance of the semiconductor device, side wall surface area of the source/drain contact is reduced in size. However, to mitigate or avoid an increase in contact resistance between the source/drain contact and the respective source/drain due to the reduced area of the source/drain contact, a conformal contact layer of a desired thickness is disposed around the source/drain to reduce the contact resistance to the source/drain. This may allow, for example, the source/drain contact to not have to extend down adjacent to the entire region of the source/drain to provide a sufficient lower, contact resistance between the source/drain contact and the respective source/drain. Instead, as an example, the source/drain contact may only have to extend down adjacent to an upper region of the source/drain to still achieve a desired, lower contact resistance, which results in a reduced area source/drain contact for reducing parasitic capacitance between the source/drain contact and the gate for improved performance. Further, as an example, the source/drain contact not having to extend down adjacent to the entire region of the source/drain may relax contact etch requirements for fabricating the semiconductor device, because a contact fill cavity etched during fabrication of the semiconductor device for receiving the contact fill material to form the source/drain contact does not have to be etched of a larger width to allow the contact fill material to be in surface contact with the contact layer adjacent to the entire region of the source/drain. Further, because a conformal contact layer may allow the source/drain contact to only have to extend down adjacent to an upper region of the source/drain to still achieve a desired, lower contact resistance, the conformal contact layer can be used as an etch stop for etching the contact fill cavity for receiving the contact fill material to form the source/drain contact.

In this regard in one aspect, a semiconductor device is provided. The semiconductor device comprises a conduction channel disposed above a substrate, and comprising one or more channel structures each comprising a semiconductor material. The semiconductor device comprises a source disposed in a first end portion of the conduction channel, and a drain disposed in a second end portion of the conduction channel. The semiconductor device also comprises a gate disposed adjacent to the conduction channel. The semiconductor device also comprises a first conformal contact layer disposed around and contacting substantially all surface area of the source and the first end portion of the conduction channel. The semiconductor device also comprises a second conformal contact layer disposed around and contacting substantially all surface area of the drain and the second end portion of the conduction channel. The semiconductor device also comprises a source contact disposed around and contacting only a portion of a surface area of the first conformal contact layer in contact with the source. The semiconductor device also comprises a drain contact disposed around and contacting only a portion of a surface area of the second conformal contact layer in contact with the drain.

In another aspect, a semiconductor device is provided. The semiconductor device comprises a first means for conduction disposed above a substrate comprising one or more means for providing a conduction channel in response to a gate voltage applied to a gate means disposed adjacent to the means for providing the conduction channel. The semiconductor device also comprises a source means disposed in the means for providing the conduction channel. The semiconductor device also comprises a drain means disposed in the means for providing the conduction channel. The means for providing the conduction channel is disposed between and in electrical contact with the source means and the drain means. The semiconductor device also comprises a first means for conforming a first conformal contact layer disposed around and contacting substantially all surface area of the source means. The semiconductor device also comprises a second means for conforming a second conformal contact layer disposed around and contacting substantially all surface area of the drain means. The semiconductor device also comprises a means for providing a source contact disposed around and contacting a portion of a surface area of the first means for conforming the first conformal contact layer. The semiconductor device also comprises a means for providing a drain contact disposed around and contacting a portion of a surface area of the second means for conforming the second conformal contact layer.

In another aspect, a method for fabricating a semiconductor device is provided. The method comprises forming a conduction channel above a substrate. The conduction channel comprises one or more channel structures each comprising a semiconductor material. The method also comprises forming a source on a first end portion of the conduction channel, and forming a drain on a second end portion of the conduction channel opposite of the first end portion. The method further comprises forming a first conformal contact layer around and contacting substantially all surface area of the source and the first end portion of the conduction channel, and forming a second conformal contact layer around and contacting substantially all surface area of the drain and the second end portion of the conduction channel. The method further comprises disposing a first contact around and contacting only a portion of a surface area of the first conformal contact layer to form a source contact electrically coupled to the source. The method also comprises disposing a second contact around and contacting only a portion of a surface area of the second conformal contact layer to form a drain contact electrically coupled to the drain.

### BRIEF DESCRIPTION OF THE FIGURES

FIG. 1 is a perspective, cross-sectional diagram of a conventional complementary metal-oxide semiconductor (CMOS) fin field-effect transistor (FET) (FinFET);

FIG. 2 illustrates an exemplary semiconductor device in the form of a FinFET that includes a reduced area conformal source/drain contact for reducing parasitic capacitance between the source/drain contact and a gate that electrostatically controls conduction in a conduction channel;

FIG. 3 is a perspective cross-sectional diagram of the exemplary semiconductor device in FIG. 2;

FIGS. 4A and 4B illustrate cross-sectional views of exemplary fin-based structures that can be included in a semiconductor device such as a FinFET, wherein the fin-based structures include conventional contact structures;

FIG. 5 illustrates a cross-sectional view of an exemplary fin-based structure that can be included in a semiconductor device such as a FinFET, wherein the fin-based structure includes a conformal contact;

FIG. 6 is a flowchart illustrating an exemplary process of fabricating the semiconductor device in FIGS. 2 and 3;

FIGS. 7A-7K are perspective, cross-sectional diagrams illustrating the semiconductor device in FIG. 3 during exemplary fabrication process steps;

FIG. 8 is a block diagram of an exemplary processor-based system that can include semiconductor devices, including but not limited to the semiconductor device in FIG. 3, that include reduced area conformal source/drain contacts for reducing parasitic capacitance between the source/drain contacts and a gate; and

FIG. 9 is a block diagram showing an exemplary wireless communication system that includes devices that can include semiconductor devices, including but not limited to the semiconductor device in FIG. 3, and include a reduced area conformal source/drain contact for reducing parasitic capacitance between the source/drain contact and a gate.

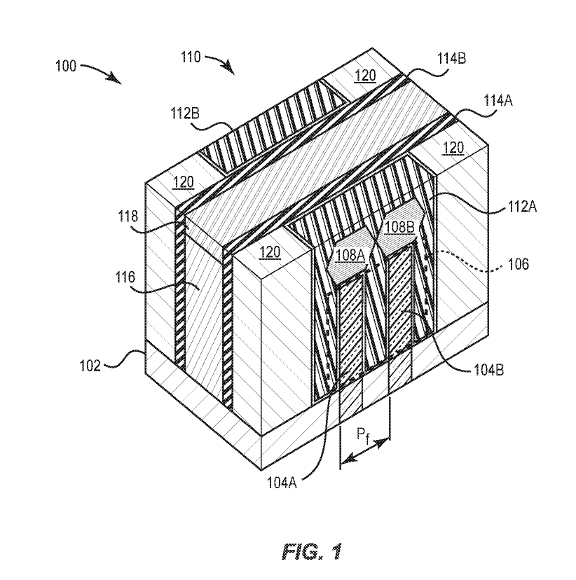

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include semiconductor devices employing reduced area conformal contacts for reduced parasitic capacitance. Related methods are also disclosed. Reducing side wall surface area of conformal contacts can reduce parasitic capacitance between contacts and a gate of the semiconductor device to improve device performance. In this regard, in exemplary aspects disclosed herein, a semiconductor device is provided that includes a conduction channel formed of one or more channel structures formed of a semiconductor material. For example, if the semiconductor device is a fin field-effect transistor (FET) (FinFET), the channel structure(s) is a fin of a semiconductor material. The semiconductor device also include a source and a drain that are formed (e.g., by doping the channel structure or epitaxial growth on the channel structure) in contact with the channel structure to form a conduction path between the source and the drain when the conduction channel is activated. A “wrap-around” gate of a gate material is disposed over at least a portion of the conduction channel to provide electrostatic control of the conduction channel. The semiconductor device also includes source and drain contacts formed of a conductive contact fill material (e.g., a fill metal material) in contact with a contact layer (e.g., a contact metal or silicide) disposed in contact to the respective source and drain, to provide electrical contacts to the source and drain. A spacer of a dielectric material is located between the gate and the source and drain contacts.

To reduce the parasitic capacitance between the gate and the source and/or drain (source/drain) contacts for improved performance of the semiconductor device, side wall surface area of the source/drain contact is reduced in size. However, to mitigate or avoid an increase in contact resistance between the source/drain contact and the respective source/drain due to the reduced area of the source/drain contact, a conformal contact layer of a desired thickness is disposed around the source/drain to reduce the contact resistance to the source/drain. This may allow, for example, the source/drain contact to not have to extend down adjacent to the entire region of the source/drain to provide a sufficient lower, contact resistance between the source/drain contact and the respective source/drain. Instead, as an example, the source/drain contact may only have to extend down adjacent to an upper region of the source/drain to still achieve a desired, lower contact resistance, which results in a reduced area source/drain contact for reducing parasitic capacitance between the source/drain contact and the gate for improved performance. Further, as an example, the source/drain contact not having to extend down adjacent to the entire region of the source/drain may relax contact etch requirements for fabricating the semiconductor device, because a contact fill cavity etched during fabrication of the semiconductor device for receiving the contact fill material to form the source/drain contact does not have to be etched of a larger width to allow the contact fill material to be in surface contact with the contact layer adjacent to the entire region of the source/drain. Further, because a conformal contact layer may allow the source/drain contact to only have to extend down adjacent to an upper region of the source/drain to still achieve a desired, lower contact resistance, the conformal contact layer can be used as an etch stop for etching the contact fill cavity for receiving the contact fill material to form the source/drain contact.

Fin-based devices represent a significant advance in IC technology. Fin-based devices are three-dimensional structures on the surface of a semiconductor substrate. A fin-based transistor, which may be a fin-based metal-oxide semiconductor field-effect transistor (MOSFET), may be referred to as a FinFET. A nanowire field-effect transistor (FET) also represents a significant advance in IC technology. A gate-all-around (GAA) nanowire-based device is also a three-dimensional structure on the surface of a semiconductor substrate. A GAA nanowire-based device includes doped portions of the nanowire that contact a channel region and serve as the source and drain regions of the device. A GAA nanowire-based device is also an example of a MOSFET device. In one configuration, a gate-all-around nanowire FET is described.

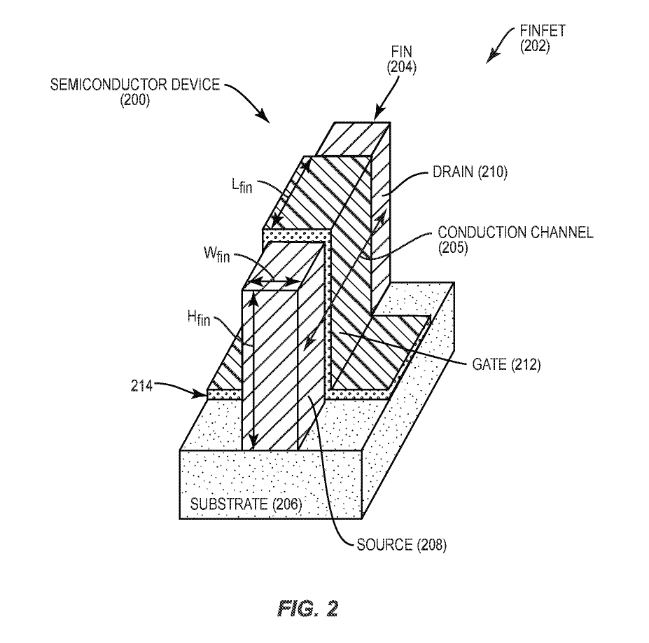

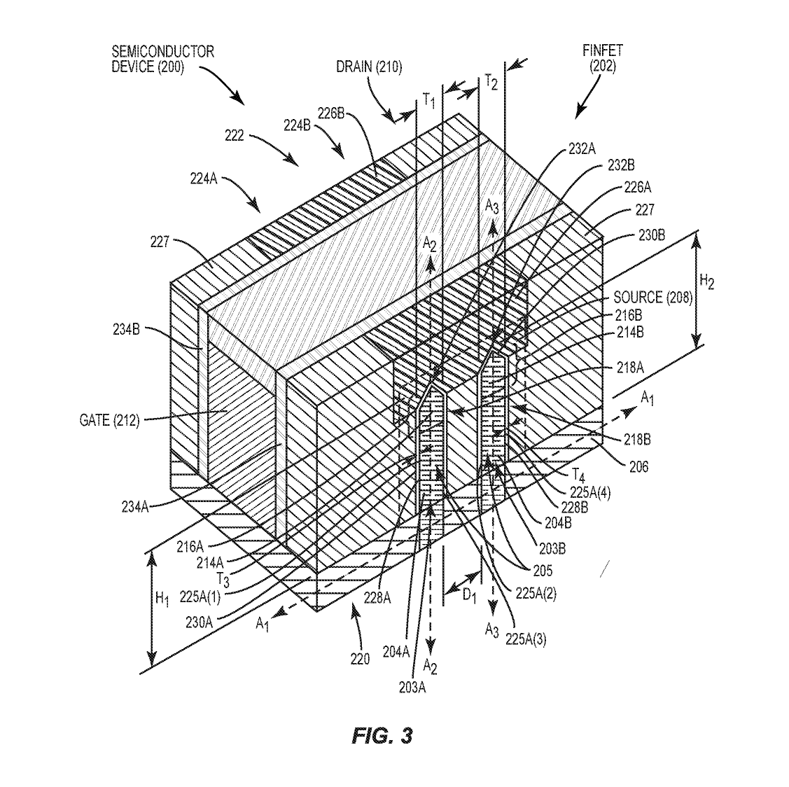

In this regard, FIG. 2 illustrates an exemplary semiconductor device 200 in the form of a FinFET 202. As will be discussed in more detail below for FIG. 3, the FinFET 202 includes reduced area conformal source and drain contacts for reduced parasitic capacitance between the source/drain contacts and a gate that electrostatically controls conduction in a conduction channel. The FinFET 202 includes a fin 204 that is a semiconductor material to form a conduction channel 205 when activated. The fin 204 may be epitaxially grown on a substrate 206 or otherwise formed on the substrate 206. The substrate 206 may be a semiconductor substrate or other like supporting layer, for example, comprised of an oxide layer, a nitride layer, a metal oxide layer, or a silicon layer. The fin 204 includes a source 208 and a drain 210. A “wrap-around” gate 212 is disposed on the fin 204 and on the substrate 206 through a gate insulator 214. A height, H_{fin}, a width, W_{fin}, and a length, L_{fin}, represent the dimensions of the fin 204. The physical size of the FinFET 202 may be smaller than a planar MOSFET device. This reduction in physical size allows for more devices per unit area on a semiconductor die.

The performance of MOSFET devices can be affected by numerous factors including channel length, strain, and external resistance. One substantial factor that contributes to external resistance is a contact resistance between the source/drain regions and the conductive layers. Contact resistance is a device performance and scaling limiter for advanced technology nodes in which the geometry and “pitch” (spacing) between devices is dramatically reduced.

As device geometries are reduced, and additional device structures are added to an IC, contact resistance becomes a substantial device performance and scaling limiter. For example, in advanced technology nodes in which the geometry and “pitch” (spacing) between devices is dramatically reduced, contact resistance may prohibit proper device operation. In particular, a reduced contact resistance is desired to continue support of improved device performance and density scaling for advanced logic technology, such as seven (7) nanometer (nm) logic technology and beyond. In fin-based devices as well as GAA nanowire-based devices, however, the geometry of the fins/gates, and the fin/gate pitch causes substantial contact resistance.

To further illustrate the reduced area conformal source/drain contact for providing contacts to the source 208 and the drain 210, and reducing parasitic capacitance between the source/drain contact and the gate 212 in the FinFET 202 in FIG. 2, FIG. 3 is provided. FIG. 3 is a perspective cross-sectional diagram of the semiconductor device 200 in FIG. 2, which is the FinFET 202 in this example. The FinFET 202 includes the substrate 206 and a conduction channel 205 formed by two channel structures 203A, 203B provided in the form of fins 204A, 204B in this example, which are made of a semiconductor material, to form the conduction channel 205 (see FIG. 2). The substrate 206 is disposed along a longitudinal axis A₁. The fins 204A, 204B can be disposed on and/or above the substrate 206 or partially formed within the substrate 206. The fins 204A, 204B each have longitudinal axes A₂, A₃ that are substantially orthogonal to the longitudinal axis A₁ of the substrate 206. The fins 204A, 204B do not contact each other. The fins 204A, 204B are of height H₁ and H₂, and thickness T₁, T₂, and are spaced apart by a distance D₁, which may be at least nine (9) nm for example, and fourteen (14) nm as a specific example. For example, the ratio of the distance D1 between the fins 204A, 204B and the height H₁ and H₁ of the fins 204A, 204B may be approximately 2.0 or less.

The FinFET 202 further includes source/drain elements 214A, 214B disposed above or within the fins 204A, 204B at first and second end portions 218A, 218B of the fins 204A, 204B to form a respective source 208 and drain 210. By “source/drain,” it is meant that either the source- or drain-related element is shown on a front side 220 of the FinFET 202 in FIG. 3. A rear side 222 of the FinFET 202 has the same structure as shown on the front side 220, but illustrates first and second end portions 224A, 224B of the fins 204A, 204B.

With continuing reference to FIG. 3, the source/drain elements 214A, 214B can be formed in the first and second end portions 218A, 218B of the fins 204A, 204B by doping upper regions 216A, 216B of the fins 204A, 204B with a specific type of charge carrier such that the upper regions 216A, 216B of the fins 204A, 204B are conductive to form the source 208 or the drain 210. Alternatively, the source/drain elements 214A, 214B can be epitaxially grown on the fins 204A, 204B to form the source 208/drain 210 as another example. The fins 204A, 204B are disposed between the source 208 and the drain 210. The fins 204, 204B, whose first and second end portions 218A, 218B are in electrical contact with the source 208, and whose first and second end portions 224A, 224B are in electrical contact with the drain 210, form the conduction channel 205 between the source 208 and the drain 210. The fins 204A, 204B each comprise a respective first side wall 225A(1), 225A(2) and a second side wall 225A(3), 225A(4) having a substantially straight profile and elongated in the direction of the longitudinal axes A₂, A₃ such that the fins 204A, 204B have a substantially straight profile.

With continuing reference to FIG. 3, to provide a contact to the source 208 and drain 210, source/drain contacts 226A, 226B are provided in an interlayer dielectric (ILD) 227 that surrounds the fins 204A, 204B. The ILD 227 isolates the active components of the FinFET 202 from other devices disposed near the FinFET 202. The source/drain contact 226A is disposed above and in contact with the source/drain elements 214A, 214B. The source/drain contact 226B is also disposed above and in contact with the source/drain elements on the rear side 222 of the FinFET 202. Using source/drain contact 226A as an example, the source/drain contact 226A is disposed around and contacting only a portion of a surface area 228A, 228B of first and second conformal contact layers 230A, 230B that are disposed around and contacting substantially all surface area of the source/drain elements 214A, 214B. In this example, the source/drain contact 226A is disposed around and contacting only a top surface area 232A, 232B of first and second conformal contact layers 230A, 230B in the upper regions 216A, 216B of the fins 204A, 204B. The first and second conformal contact layers 230A, 230B are conformal layers. Further, the first and second conformal contact layers 230A, 230B are also contacting substantially all surface area of the fins 204A, 204A above the substrate 206. In this manner, a conduction path is provided between the fins 204A, 204B and the source/drain contact 226A down to the substrate 206, but without the source/drain contact 226A having to extend down to the substrate 206. In this manner, the source/drain contact 226A is reduced in size and has less area. Thus, parasitic capacitance can be reduced between the source/drain contact 226A and a conformal gate 212 that are disposed on the substrate 206 and over the fins 204A, 204B to provide electrostatic control of the conduction channel in the fins 204A, 204B between the source 208 and the drain 210. The same is the case for the source/drain contact 226B.

The first and second conformal contact layers 230A, 230B are comprised of a conductive material, such as a metal material, such as Cobalt (Co), Titanium (Ti), or a Titanium (Ti) layer disposed on a Titanium Oxide (TiO₂) layer. The first and second conformal contact layers 230A, 230B could also be a silicide (e.g., Titanium (Ti) Silicon (Si) (TiSi), Cobalt (Co) Si (CoSi), Nickel (N) Silicon (Si) (NiSi)) as another example.

The thicknesses T₃, T₄ of the first and second conformal contact layers 230A, 230B is such that the desired resistance is achieved to reduce the contact resistance between the source/drain contact 226A and the source/drain elements 214A, 214B to reduce the contact resistance with the source 208 or drain 210. For example, the thicknesses T₃, T₄ of the first and second conformal contact layers 230A, 230B may be at least two (2) nm as an example, and be between approximately four (4) nanometers (nm) and six (6) nm as an example. The thickness T₃ should be chosen to provide the desired resistance of the first and second conformal contact layers 230A, 230B to reduce the contact resistance between the source/drain contact 226A and the source/drain elements 214A, 214B without the source/drain contact 226A having to extend down adjacent to the entire surface area of the fins 204A, 204B below the source/drain elements 214A, 214B and/or down to the substrate 206. For example, a ratio of the thickness T₃, T₄ of the first and second conformal contact layers 230A, 230B to the thickness T₁, T₂ of their respective fins 204A, 204B may at least twenty percent (20%) for example, and also may be less than fifty percent (50%) as another example.

To insulate the gate 212 from the source/drain contacts 226A, 226B, insulating gate spacers 234A, 234B are provided between the gate 212 and the source/drain contacts 226A, 226B. The gate spacers 234A, 234B may be provided as a dielectric material, such as a Nitride-based low-k material, or a dielectric medium such as air for example.

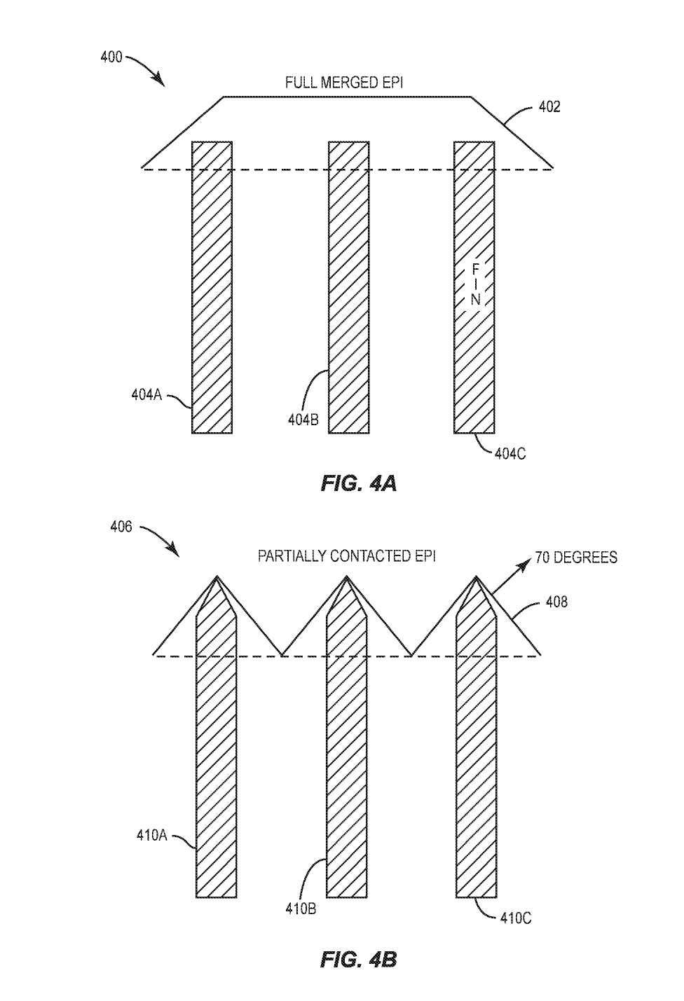

FIG. 4A illustrates a cross-sectional view of a fin-based structure 400 that includes a first conventional contact structure 402 and does not include a conformal contact layer. The fin-based structure 400 may be used within an IC, such as a FET. Fins 404A-404C may be supported by a substrate (not shown) and doped with a specific type of charge carrier, such that the fins 404A-404C are conductive. The substrate may be a semiconductor substrate, a silicon on insulator (SOI) substrate, a buried oxide (BOX) layer, or the like. An SOI substrate may be fully depleted. The fins 404A-404C may be doped with an n-type dopant or a p-type dopant depending on the type of charge carrier desired in the final device. The first conventional contact structure 402 to the fins 404A-404C is fabricated using a fully merged epitaxial growth or other like process. A contact area (CA) of the first conventional contact structure 402 provided by the fully merged epitaxial growth may be determined as follows:

CA=CD*[(NF−1)*FP+FP/cos(55°)], (1)
where:
   ‘CD’ is the critical dimension;
   ‘NF’ is the number of fins 404A-404C; and
   ‘FP’ is the fin pitch to enable the contact surface area calculation for the first conventional contact structure 402.

FIG. 4B illustrates a cross-sectional view of a fin-based structure 406 including a second conventional contact structure 408 to fins 410A-410C. The fin-based structure 406 may also be used within an IC, such as a FET. The fins 410A-410C may be supported by a substrate (not shown) and doped with a specific type of charge carrier, such that the fins 410A-410C are conductive. The fins 410A-410C may also be doped with an n-type dopant or a p-type dopant depending on the type of charge carrier specified for the final device. The second conventional contact structure 408 is fabricated using a partially contacted epitaxial growth or other like process. In this arrangement, the second conventional contact structure 408 is fabricated at a seventy degree(70°) angle. A contact area (CA) of the second conventional contact structure 408 provided by the partially contacted epitaxial growth may be determined as follows:

CA=CD*FP/cos(55°)*NF, (2)
where:
   ‘CD’ is the critical dimension;
   ‘NF’ is the number of fins 410A-410C; and
   ‘FP’ is the fin pitch to enable the contact surface area calculation for the second conventional contact structure 408.

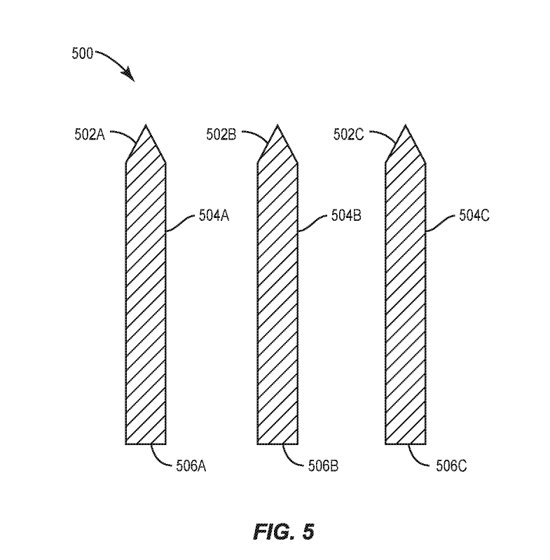

FIG. 5 illustrates a cross-sectional view of a fin-based structure 500 that includes conformal contact layers 502A-502C, to illustrate an example of how the conformal contact layers 230A, 230B may be disposed around the fins 204A, 204B in the FinFET 202 in FIG. 3. The fin-based structure 500 may also be used within an IC, such as the FinFET 202 in FIG. 3. The conformal contact layers 502A-502B are disposed around and contacting substantially all surface areas 504A-504C of respective fins 506A-506C. The fins 506A-506C may be supported by a substrate (not shown) and doped with a specific type of charge carrier, such that a portion of the fins 506A-506C are conductive, such as to form a source or drain. The fins 506A-506C may be doped with an n-type dopant or a p-type dopant depending on the type of charge carrier desired in the final device. The conformal contact layers 502A-502C can be fabricated using, for example, a metal-insulator-semiconductor (MIS) contact or a direct contact, rather than relying on growth or other like process.

The contact area of the conformal contact layers 502A-502C to a fin 506A-506C provided by the MIS contact or the direct contact may be determined as follows:

CA=CD*(2*FH+FW/cos(55°))*NF, (3)

where:
‘CD’ is the critical dimension;
‘NF’ is the number of fins 506A-506C;
‘FH’ is the fin height; and
‘FW’ is the fin width.

For example, in seven (7) nm logic technology, the following dimension may be present: CD=14 nm, FP=24 nm, FH=35 nm, FW=6 nm, and NF=3 nm. Based on these dimensions, the contact surface area for the first conventional contact structure 402 in FIG. 4A may be computed according to equation (1), such that CD=14*[(3-1)*24+24/0.57]=14*90)=>×1.00. Based on these values, the contact surface area for the second conventional contact structure 408 in FIG. 4B may be computed according to equation (2), such that CD=14*24/0.57*3=14*126=>×1.40. Using these same values, the contact surface area for the conformal contact layer 502A-502C in FIG. 5 may be computed according to equation (3), such that CD=14*(2*35+6/0.57)*3=14*241=>×2.68. Assuming FH=60 nm, the contact surface area for the conformal contact layer 502A-502C in FIG. 5 is ×4.35 greater than the contact surface area for the first conventional contact structure 402 in FIG. 4A, and ×3.11 greater than the contact surface area for the second conventional contact structure 408 in FIG. 4B, which may reduce the contact resistance by approximately fifty percent (50%).

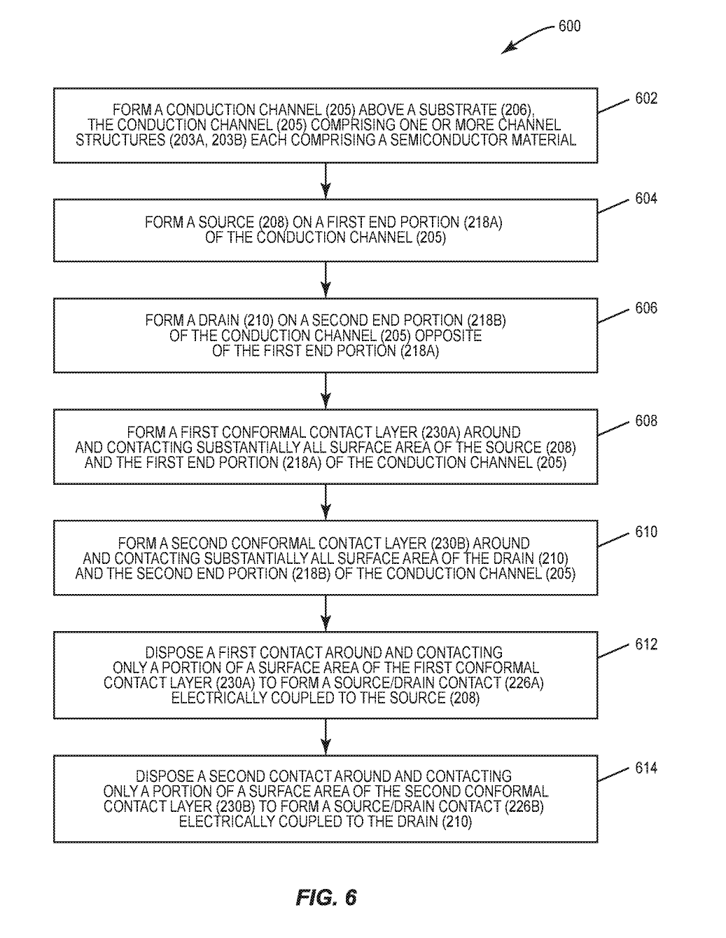

FIG. 6 is a flowchart illustrating an exemplary process 600 of fabricating the semiconductor device 200 in FIG. 3 that includes a reduced area conformal source/drain contact for reduced parasitic capacitance. A first step involves forming the conduction channel 205 above the substrate 206, wherein the conduction channel 205 comprises one or more channel structures 203A, 203B each comprising a semiconductor material (block 602). Another step involves forming the source 208 on the first end portion 218A of the conduction channel 205 (block 604). Another step involves forming the drain 210 on the second end portion 218B of the conduction channel 205 opposite of the first end portion 218A (block 606). Another step involves forming the first conformal contact layer 230A around and contacting substantially all surface area of the source 208 and the first end portion 218A of the conduction channel 205 (block 608). Another step involves forming a second conformal contact layer 230B around and contacting substantially all surface area of the drain 210 and the second end portion 218B of the conduction channel 205 (block 610). Another step involves disposing the first contact around and contacting only a portion of a surface area of the first conformal contact layer 230A to form a source/drain contact 226A electrically coupled to the source 208 (block 612). Another step involves disposing a second contact around and contacting only a portion of a surface area of the second conformal contact layer 230B to form a source/drain contact 226B electrically coupled to the drain 210 (block 614).

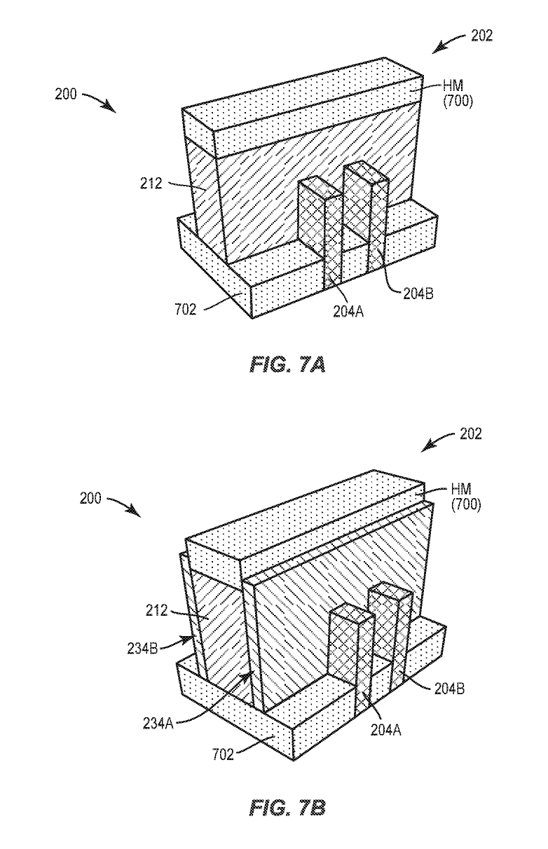

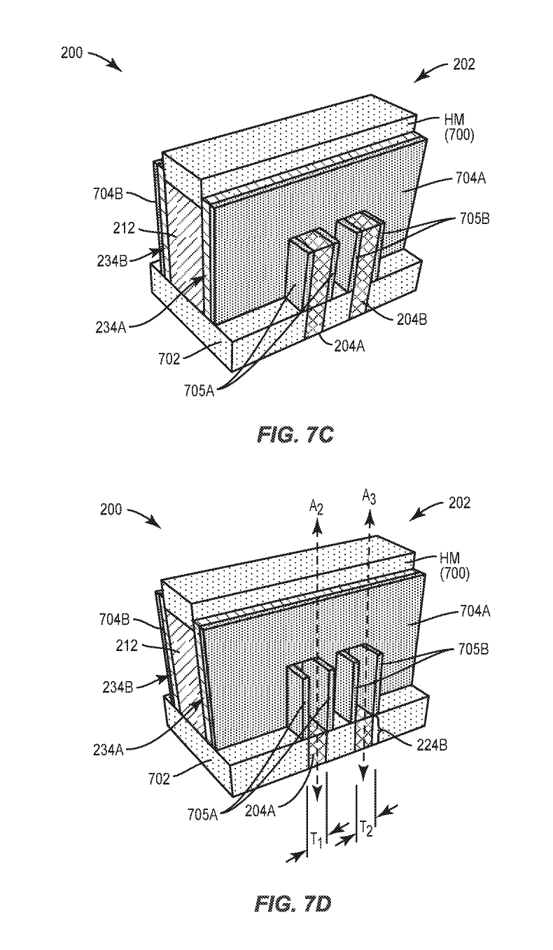

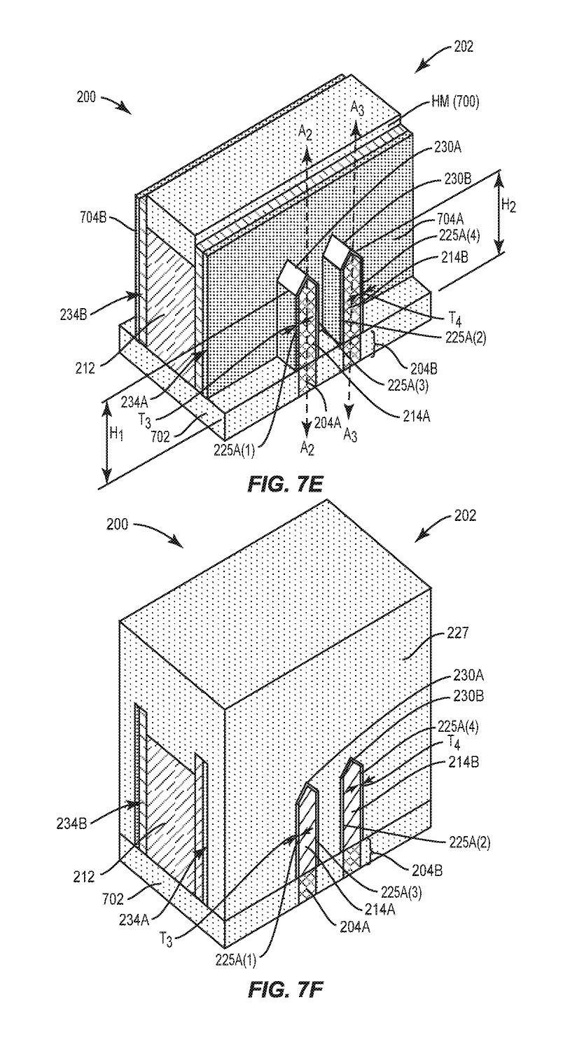

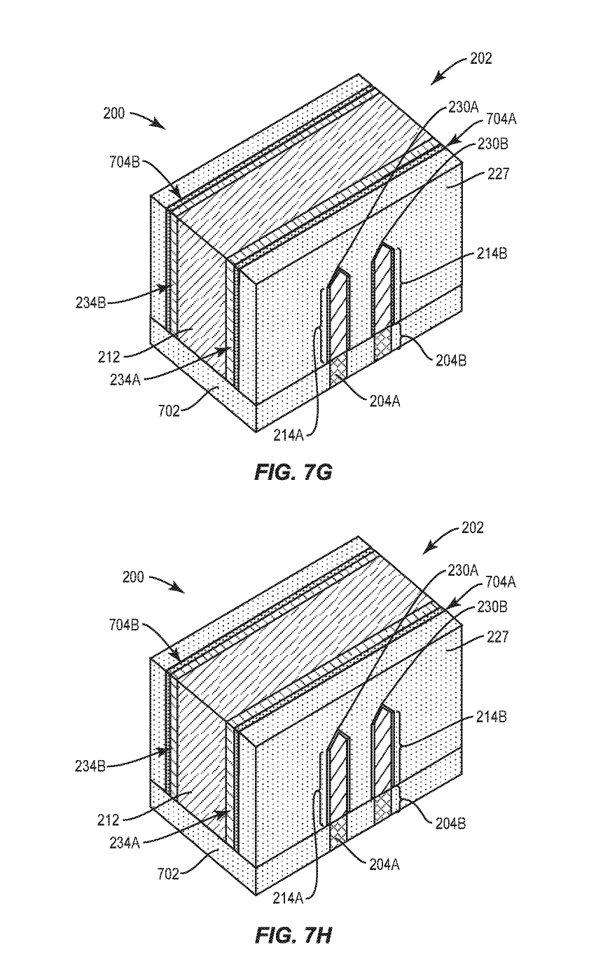

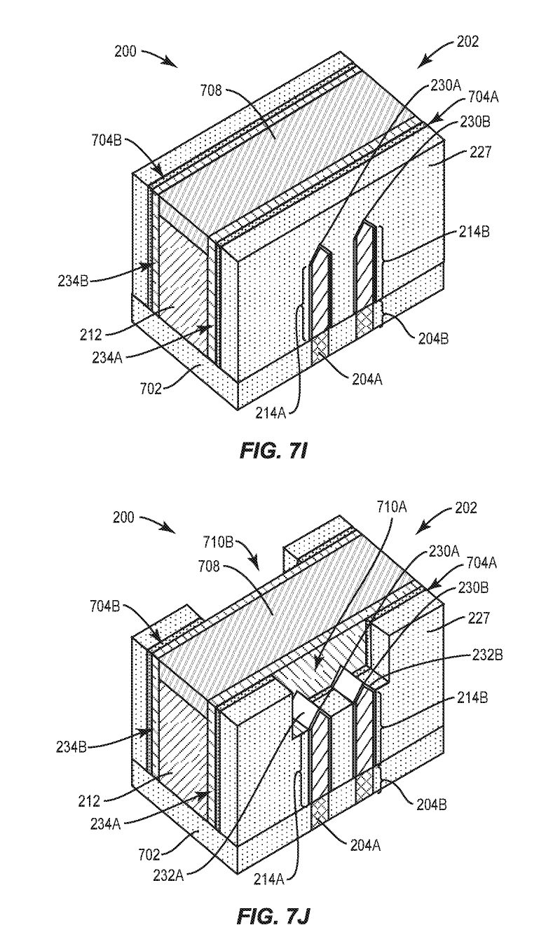

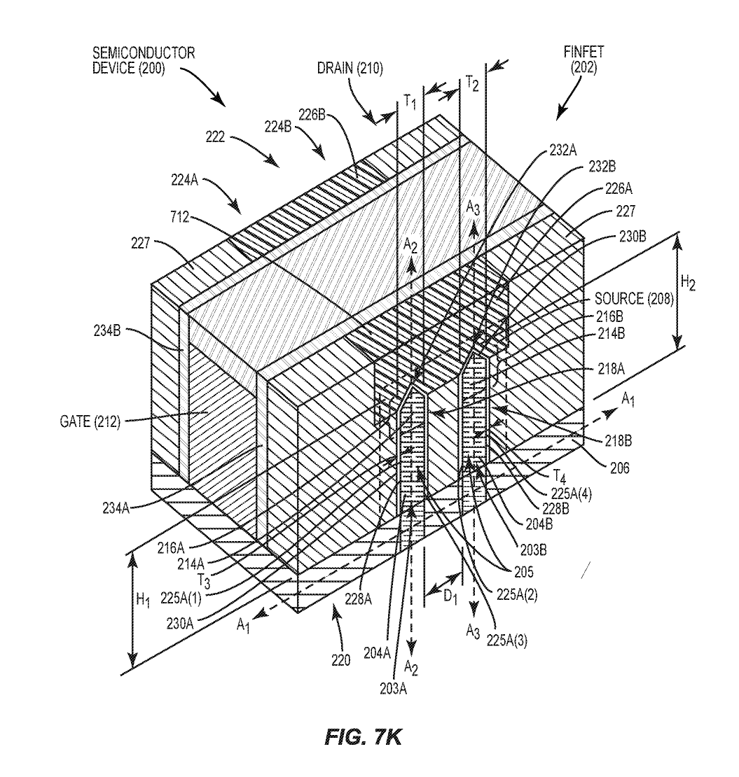

FIGS. 7A-7K are perspective, cross-sectional diagrams illustrating the semiconductor device 200 in FIG. 3 during exemplary fabrication process steps. In FIG. 7A, a hard mask (HM) 700 (e.g., oxide) is arranged on the gate 212 during the patterning of the gate 212. The gate 212 is supported by a shallow trench isolation (STI) region 702, which may be supported by a substrate. The source/drain regions of the gate 112 can be provided by regrown source 208/drains 210.

In FIG. 7B, gate spacers 234A, 234B (e.g., a nitride-based low-K gate spacer) are formed on sidewalls of the gate 212 and the hard mask 700. For example, as shown in FIG. 7C, an optional source/drain spacer 704A, 704B is formed on the sidewalls of the gate 212 and the hard mask 700. The optional source/drain spacers 704A, 704B are formed from spacer structures 705A, 705B that allow for the fins 204A, 204B to be provided having a substantially straight profile so that when a contact fill metal is later disposed in contact with the source 208 and drain 210, the contact area between the contact fill metal and the source 208 and drain 210 can be minimized to minimize parasitic capacitance between the gate 212 and the contact fill metal. If these spacer structures 705A, 705B were not provided, the fins 204A, 204B and the source 208 and drain 210 formed therein or above may not be formed having a substantially straight profile to minimize contact area. For example, using an epitaxial process to grow the source/drain elements 214A, 214B without the spacer structures 705A, 705B may cause the source/drain elements 214A, 214B to be diamond-shaped and have a greater top surface area that would increase the parasitic capacitance when the contact fill material is disposed and coupled to the source/drain elements 214A, 214B.

As shown in FIG. 7D, the fins 204A, 204B are recess etched through the optional source/drain spacers 704A, 704B and the gate spacers 234A, 234B. As shown in FIG. 7E, in this example, the source/drain elements 214A, 214B may be grown on the fins 204A, 204B using epitaxial growth. The regrown source/drain elements 214A, 214B may be formed with a controlled (e.g., <111> Miller index) facet formation without merging the regrown source/drain elements 214A, 214B. For example, epitaxial growth of phosphorous doped silicon (SiP), carbon phosphorous doped silicon (SiCP), or phosphorous doped germanium (GeP) may form regrown S/D regions of an n-type (e.g., an NFET). Similarly, epitaxial growth of boron doped silicon germanium (SiGeB), or boron doped germanium (GeB) may form regrown S/D regions of a p-type (e.g., a PFET). In this arrangement, the regrown source/drain elements 214A, 214B have substantially parallel sidewalls. Following completion of the gate 212, a conformal contact layer 230A, 230B is formed to surround and conform to the regrown source/drain elements 214A, 214B. The conformal contact layers 230A, 230B surround the respective first and second side walls 225A(1), 225A(2), 225A(3), 225A(4) of the fins 204A, 204B. The conformal contact layers 230A, 230B may be formed by an atomic layer deposition (ALD) process for example to keep the conformal contact layers 230A, 230B thin. As discussed above, providing the conformal contact layers 230A, 230B to surround and conform to the regrown source/drain elements 214A, 214B provides for the overall resistance of the source 208 and drain 210 to be reduced. In this example, the conformal contact layers 230A, 230B extend down to the substrate 206, but as will be later shown, the contact fill metal does not.

As shown in FIG. 7F, the ILD 227 is deposited on the FinFET 202. As shown in FIG. 7G, a chemical mechanical planarization (CMP) process can be performed on the ILD 227 to expose the gate 212. Further, as shown in FIG. 7H, the dummy gate is removed to form the gate 212 and expose the gate 212 using a CMP process that stops on the ILD 227. Further, as shown in FIG. 7I, a conductive layer is etched and a sacrificial gate 708 is deposited. A CMP process may be performed on the sacrificial gate 708.

As shown in FIG. 7J, an etch of the ILD 227 and the source/drain spacers 704A, 704B is performed to expose the source/drain elements 214A, 214B and stop on conformal contact layers 230A, 230B and the gate spacers 234A, 234B. The ILD 227 is etched to form contact fill cavities 710A, 710B for forming the source/drain contacts 226A, 226B. The etch may be a selective etch that is based on time or based on using the top surface areas 232A, 232B of the conformal contact layers 230A, 230B as an etch stop layer. As shown in FIG. 7K, a contact fill material 712 is filled in the contact fill cavities 710A, 710B (see FIG. 7J) to form the source/drain contact 226A, and similarly the source/drain contact 226B. For example, a dual damascene process may be employed to perform the etch of the ILD 227 and to fill the contact fill cavities 710A, 710B with the contact fill material 712 to form the source/drain contacts 226A, 226B. In this example, without limitation, by etching the contact fill cavities 710A, 710B only down to substantially the top surface areas 232A, 232B of the conformal contact layers 230A, 230B to be in substantial contact with the top surface areas 232A, 232B of the conformal contact layers 230A, 230B, but not in contact with the conformal contact layers 230A, 230B extending down adjacent to the side walls 225A(1)-225A(4) of the fins 204A, 204B, the contact fill material 712 is minimized to form the source/drain contacts 226A, 226B to minimize parasitic capacitance. The contact fill material 712 is partially filled in space between the fins 204A, 204B, and substantially at the top surface areas 232A, 232B of the conformal contact layers 230A, 230B. But, the conformal contact layers 230A, 230B extending down adjacent to the side walls 225A(1)-225A(4) of the fins 204A, 204B lowers the resistance of the fins 204A, 204B to lower the overall resistance.

The process flow for semiconductor fabrication of a reduced area conformal source and drain contacts for reduced parasitic capacitance between the source/drain contacts and a gate that electrostatically controls conduction in a conduction channel may include front-end-of-line (FEOL) processes, middle-of-line (MOL) processes, and back-end-of-line (BEOL) processes. It will be understood that the term “layer” includes film and is not to be construed as indicating a vertical or horizontal thickness unless otherwise stated. As described herein, the term “substrate” or may refer to a substrate of a diced wafer or may refer to the substrate of a wafer that is not diced. Similarly, the terms wafer and die may be used interchangeably unless such interchanging would tax credulity.

A semiconductor device, such as the FinFET 202 in FIGS. 2 and 3 for example, that includes a reduced area conformal source/drain contact for reduced parasitic capacitance between the source/drain contact and a gate that electrostatically controls conduction in a conduction channel may be provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

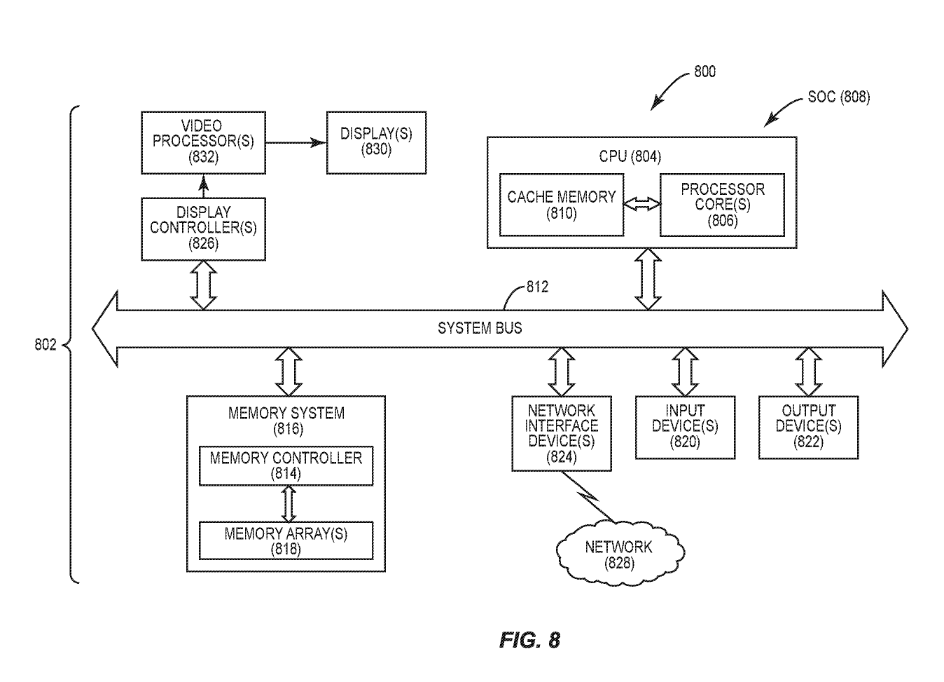

In this regard, FIG. 8 is a block diagram of an exemplary processor-based system 800 that can include semiconductor devices 802, such as the FinFET 202 in FIGS. 2 and 3 for example, that include a reduced area conformal source/drain contact for reduced parasitic capacitance between the source/drain contact and a gate that electrostatically controls conduction in a conduction channel. In this example, the processor-based system 800 includes a central processing unit (CPU) 804 that includes one or more processor cores 806. The processor-based system 800 may be provided as a system-on-a-chip (SoC) 808. The CPU 804 may have cache memory 810 coupled to the processor(s) 806 for rapid access to temporarily stored data. The CPU(s) 804 is coupled to a system bus 812 and can intercouple master and slave devices included in the processor-based system 800. As is well known, the CPU 804 communicates with these other devices by exchanging address, control, and data information over the system bus 812. For example, the CPU 804 can communicate bus transaction requests to a memory controller 814 in a memory system 816 as an example of a slave device. Although not illustrated in FIG. 8, multiple system buses 812 could be provided, wherein each system bus 812 constitutes a different fabric. In this example, the memory controller 814 is configured to provide memory access requests to one or more memory arrays 818 in the memory system 816.

Other devices can be connected to the system bus 812. As illustrated in FIG. 8, these devices can include the memory system 816, one or more input devices 820, one or more output devices 822, one or more network interface devices 824, and one or more display controllers 826, as examples. The input device(s) 820 can include any type of input device, including but not limited to input keys, switches, voice processors, etc. The output device(s) 822 can include any type of output device, including but not limited to audio, video, other visual indicators, etc. The network interface device(s) 824 can be any devices configured to allow exchange of data to and from a network 828. The network 828 can be any type of network, including but not limited to a wired or wireless network, a private or public network, a local area network (LAN), a wireless local area network (WLAN), a wide area network (WAN), a BLUETOOTH™ network, and the Internet. The network interface device(s) 824 can be configured to support any type of communications protocol desired.

The CPU 804 may also be configured to access the display controller(s) 826 over the system bus 812 to control information sent to one or more displays 830. The display controller(s) 826 sends information to the display(s) 830 to be displayed via one or more video processors 832, which process the information to be displayed into a format suitable for the display(s) 830. The display(s) 830 can include any type of display, including but not limited to a cathode ray tube (CRT), a liquid crystal display (LCD), a plasma display, etc.

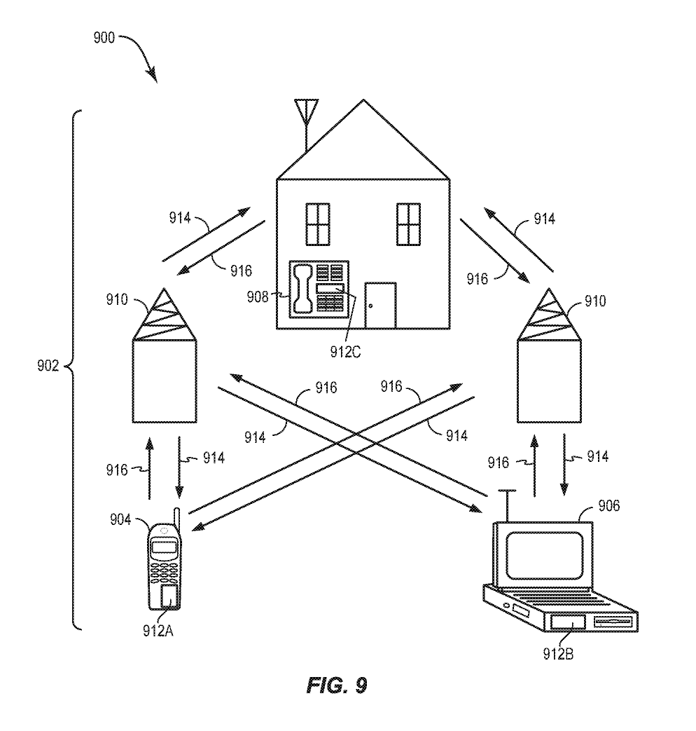

FIG. 9 is a block diagram showing an exemplary wireless communication system 900 that can include devices that include semiconductor devices 902, such as the FinFET 202 in FIGS. 2 and 3 for example, that include a reduced area conformal source/drain contact for reduced parasitic capacitance between the source/drain contact and a gate that electrostatically controls conduction in a conduction channel 205. For purposes of illustration, FIG. 9 illustrates three (3) remote units 904, 906, and 908 and two (2) base stations 910. It will be recognized that wireless communication systems may have many more remote units and base stations. Remote units 904, 906, 908 can include IC devices 912A, 912B, and 912C that include the semiconductor devices 902. It will be recognized that other devices may also include the disclosed contacts, such as the base stations, switching devices, and network equipment. FIG. 9 shows forward link signals 914 from the base station 910 to the remote units 904, 906, 908 and reverse link signals 916 from the remote units 904, 906, 908 to base stations 910.

In FIG. 9, the remote unit 904 is shown as a mobile telephone, remote unit 906 is shown as a portable computer, and remote unit 908 is shown as a fixed location remote unit in a wireless local loop system. For example, the remote units 904, 906, 908 may be a mobile phone, a hand-held personal communication systems (PCS) unit, a portable data unit such as a personal data assistant (PDA), a GPS enabled device, a navigation device, a set top box, a music player, a video player, an entertainment unit, a fixed location data unit such as meter reading equipment, a set top box, an entertainment unit, a communications device, a fixed location data unit, a mobile location data unit, a cellular phone, a smart phone, a tablet, a phablet, a server, a computer, a portable computer, a desktop computer, a monitor, a computer monitor, a television, a tuner, a radio, a satellite radio, a music player, a digital music player, a portable music player, a digital video player, a video player, a digital video disc (DVD) player, a portable digital video player, an automobile, or other devices that store or retrieve data or computer instructions, or combinations thereof. Although FIG. 9 illustrates remote units according to the aspects of the disclosure, the disclosure is not limited to these exemplary illustrated units.

Those of skill in the art will further appreciate that the various illustrative logical blocks, modules, circuits, and algorithms described in connection with the aspects disclosed herein may be implemented as electronic hardware, instructions stored in memory or in another computer-readable medium and executed by a processor or other processing device, or combinations of both. The master and slave devices described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flow chart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

What is claimed is:

1. A semiconductor device, comprising:
a conduction channel disposed above a substrate, the conduction channel comprising one or more channel structures each comprising a semiconductor material;
a source disposed in a first end portion of the conduction channel;
a drain disposed in a second end portion of the conduction channel;
a gate disposed adjacent to the conduction channel;
a first conformal contact layer disposed around and contacting substantially all surface area of the source and the first end portion of the conduction channel;
a second conformal contact layer disposed around and contacting substantially all surface area of the drain and the second end portion of the conduction channel;
a source contact disposed around and contacting only a portion of a surface area of the first conformal contact layer disposed in contact with the source; and
a drain contact disposed around and contacting only a portion of a surface area of the second conformal contact layer disposed in contact with the drain.

2. The semiconductor device of claim 1, wherein:
the source contact is disposed around and contacts substantially a top surface area of the first conformal contact layer; and
the drain contact is disposed around and contacts substantially a top surface area of the second conformal contact layer.

3. The semiconductor device of claim 1, wherein one or more channel structures comprises one or more fin structures having a longitudinal axis extend substantially orthogonal to a longitudinal axis of the substrate, the one of more fin structures having a substantially straight profile.

4. The semiconductor device of claim 3, wherein the one or more fin structures each comprise a first side wall and a second side wall both extending in a direction of the longitudinal axis of the one or more fin structures, each of the first and second side walls having a substantially straight profile.

5. The semiconductor device of claim 1, wherein each of the one or more channel structures do not contact each other.

6. The semiconductor device of claim 1, wherein the one or more channel structures are spaced apart by at least nine (9) nanometers (nm).

7. The semiconductor device of claim 1, wherein a ratio of a distance between each of the one or more channel structures and a height of the one or more channel structures is approximately 2.0 or less.

8. The semiconductor device of claim 1, wherein:
the first conformal contact layer has a first thickness of at least two (2) nanometers (nm); and
the second conformal contact layer has a first thickness of at least two (2) nm.

9. The semiconductor device of claim 1, wherein:
the first conformal contact layer has a thickness between approximately four (4) and six (6) nm; and
the second wrap-around contact layer has a thickness between approximately four (4) and six (6) nm.

10. The semiconductor device of claim 1, wherein:
a ratio of thickness of the first conformal contact layer to a thickness of a first channel structure among one or more channel structures is at least approximately twenty percent (20%); and
a ratio of thickness of the second conformal contact layer to a thickness of a second channel structure among the one or more channel structures with the source disposed therein is at least approximately twenty percent (20%).

11. The semiconductor device of claim 1, further comprising a first gate spacer comprising a dielectric material between the gate and the source contact, and a second gate spacer between the gate and the drain contact.

12. The semiconductor device of claim 1, wherein:
the first conformal contact layer comprises a silicide material; and
the second conformal contact layer comprises a silicide material.

13. The semiconductor device of claim 1, wherein:
the first conformal contact layer comprises a metal material; and
the second conformal contact layer comprises a metal material.

14. The semiconductor device of claim 1, wherein:
the first conformal contact layer comprises Titanium (Ti); and
the second conformal contact layer comprises Titanium (Ti).

15. The semiconductor device of claim 1, wherein:
the first conformal contact layer comprises a Titanium Oxide (TiO₂) layer and a Titanium (Ti) layer disposed on the Titanium Oxide (TiO₂) layer; and
the second conformal contact layer comprises a Titanium Oxide (TiO₂) layer and a Titanium (Ti) layer disposed on the Titanium Oxide (TiO₂) layer.

16. The semiconductor device of claim 1, wherein:
the first conformal contact layer comprises Cobalt (Co); and
the second conformal contact layer comprises Cobalt (Co).

17. The semiconductor device of claim 11, wherein the first gate spacer comprises a Nitride-based material and the second gate spacer comprises a Nitride-based material.

18. The semiconductor device of claim 1, wherein the one or more channel structures comprise one or more fins.

19. The semiconductor device of claim 1, wherein the one or more channel structures comprise one or more nanowires.

20. The semiconductor device of claim 1 integrated into an integrated circuit (IC).

21. The semiconductor device of claim 1 integrated into a semiconductor die.

22. The semiconductor device of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

23. A semiconductor device, comprising:
a first means for conduction disposed above a substrate comprising one or more means for providing a conduction channel in response to a gate voltage applied to a gate means disposed adjacent to the means for providing the conduction channel;
a source means disposed in the means for providing the conduction channel;
a drain means disposed in the means for providing the conduction channel;
the means for providing the conduction channel disposed between and in electrical contact with the source means and the drain means;
a first means for conforming a first conformal contact layer disposed around and contacting substantially all surface area of the source means;
a second means for conforming a second conformal contact layer disposed around and contacting substantially all surface area of the drain means;
a means for providing a source contact disposed around and contacting a portion of a surface area of the first means for conforming the first conformal contact layer; and
a means for providing a drain contact disposed around and contacting a portion of a surface area of the second means for conforming the second conformal contact layer.

24. A method for fabricating a semiconductor device, comprising:
forming a conduction channel above a substrate, the conduction channel comprising one or more channel structures each comprising a semiconductor material;
forming a source on a first end portion of the conduction channel;
forming a drain on a second end portion of the conduction channel opposite of the first end portion;
forming a first conformal contact layer around and contacting substantially all surface area of the source and the first end portion of the conduction channel;
forming a second conformal contact layer around and contacting substantially all surface area of the drain and the second end portion of the conduction channel;
disposing a first contact around and contacting only a portion of a surface area of the first conformal contact layer to form a source contact electrically coupled to the source; and
disposing a second contact around and contacting only a portion of a surface area of the second conformal contact layer to form a drain contact electrically coupled to the drain.

25. The method of claim 24, further comprising:
forming one or more spacer structures above the substrate, the one or more spacer structures comprising a first side wall, and a second side wall located adjacent to the first side wall to form an opening between the first side wall and the second side wall; and
forming the conduction channel above the substrate by forming the one or more channel structures from the semiconductor material disposed in the opening in the one or more spacer structures.

26. The method of claim 25, wherein:
forming the source comprises epitaxially growing the source in the opening in the one or more spacer structures on the first end portion of the conduction channel; and
forming the drain comprises epitaxially growing the drain in the opening in the one or more spacer structures on the second end portion of the conduction channel.

27. The method of claim 25, wherein:
forming the source comprises doping a portion of the semiconductor material in the opening in the one or more spacer structures on the first end portion of the conduction channel; and
forming the drain comprises doping a portion of the semiconductor material in the opening in the one or more spacer structures on the second end portion of the conduction channel.

28. The method of claim 24, further comprising disposing an interlayer dielectric material around the first conformal contact layer and the second conformal contact layer.

29. The method of claim 28, further comprising:
etching a first contact fill cavity in the interlayer dielectric material down to a top surface of the first conformal contact layer; and
etching a second contact fill cavity in the interlayer dielectric material down to a top surface of the second conformal contact layer;
wherein:
disposing the first contact comprises filling the first contact fill cavity with a first contact fill metal around and contacting only the portion of the surface area of the first conformal contact layer to form the source contact electrically coupled to the source; and
disposing the second contact comprises filling the second contact fill cavity with a second contact fill metal around and contacting only the portion of the surface area of the second conformal contact layer to form the drain contact electrically coupled to the drain.

30. The method of claim 28, further comprising chemical mechanical planarizing the interlayer dielectric material down to a sacrificial gate.

31. The method of claim 30, further comprising, prior to disposing the first contact and the second contact:
disposing a first spacer layer on the substrate, adjacent to a first side of the sacrificial gate; and
disposing a second spacer layer on the substrate, adjacent to a second side of the sacrificial gate.

32. The method of claim 31, further comprising:
etching the sacrificial gate down to the substrate;
disposing the gate on the substrate between the first spacer layer and the second spacer layer;
etching the gate to form a recess area above the gate; and
disposing a gate contact on the recess area.
